(19) United States
(12) Patent Application Publication
(10) Pub. No.: US 2024/0250011 A1
(43) Pub. Date: Jul. 25, 2024

(54) FAN-OUT SEMICONDUCTOR PACKAGE AND A METHOD FOR MANUFACTURING THE SAME

(71) Applicant: Samsung Electronics Co., Ltd., Suwon-si (KR)

(72) Inventors: Myeongho HONG, Suwon-si (KR); Hyunseok CHOI, Suwon-si (KR)

(73) Assignee: Samsung Electronics Co., Ltd., Suwon-si (KR)

(21) Appl. No.: 18/351,975

(22) Filed: Jul. 13, 2023

(30) Foreign Application Priority Data
Jan. 20, 2023 (KR) 10-2023-0008849

(51) Int. Cl. H01L 23/498; H01L 21/56; H01L 23/00; H01L 23/31; H01L 23/48; H01L 23/538; H01L 25/00; H01L 25/10

(52) U.S. Cl. CPC H01L 23/49838; H01L 21/568; H01L 23/3128; H01L 23/481; H01L 23/5383; H01L 23/5389; H01L 24/08; H01L 24/16; H01L 25/105; H01L 25/50; H01L 2224/08225; H01L 2224/16227

(57) ABSTRACT

The present disclosure relates to fan-out semiconductor packages and a methods for manufacturing the same. A fan-out semiconductor package includes a substrate including a cavity, a semiconductor die within the cavity and including a plurality of connection terminals at a bottom surface thereof, a dummy die at a fan-out region within the cavity and including a plurality of through silicon vias (TSVs), a filler filling an empty space within the cavity, and a lower redistribution layer on bottom surfaces of the substrate, the semiconductor die, and the dummy die, and electrically connected to at least some of the plurality of connection terminals of the semiconductor die and the plurality of through silicon vias of the dummy die, and an upper redistribution layer on top surfaces of the substrate, the semiconductor die, and the dummy die, and electrically connected to the plurality of through silicon vias of the dummy die.

### CROSS-REFERENCE TO RELATED APPLICATION

This application claims priority to and the benefit of Korean Patent Application No. 10-2023-0008849 filed in the Korean Intellectual Property Office on Jan. 20, 2023, the entire contents of which are incorporated herein by reference.

### BACKGROUND

### (a) Field of the Invention

The present disclosure relates to fan-out semiconductor packages and/or methods for manufacturing the same.

### (b) Description of the Related Art

A size of a semiconductor die is reduced, but a function of the semiconductor die is increased. For this reason, the number of pins required for signal input/output is also increased. In response to this demand, a fan-out semiconductor packaging technology has been proposed.

The fan-out semiconductor packaging technology is a technology that extends a region in which connection terminals are disposed to an outer region of the semiconductor die. In general, the fan-out semiconductor package includes a region in which the semiconductor die is disposed and a fan-out region around the semiconductor die. Specifically, a fan-out semiconductor package obtained by providing a cavity in a center of a package substrate, disposing the semiconductor die in the cavity, and providing a redistribution layer and a solder bump on one surface of the semiconductor die is known. In this case, the package substrate corresponds to the fan-out region.

On the other hand, because the package substrate is relatively weak to heat compared to the semiconductor die, warpage is likely to occur at the package substrate when a reflow process is performed to attach the fan-out semiconductor package to another system substrate. A problem of poor connection of the solder bumps caused by the warpage occurs more easily as the fan-out region increases, and also occurs more at a corner of the package.

For example, a fan-out semiconductor package in which a dummy die is buried in a fan-out region to suppress warpage in the fan-out region has been proposed. Such a fan-out semiconductor package is briefly introduced with reference to FIGS. 1A and 1B.

FIG. 1A is a cross-sectional view of the fan-out semiconductor package in which a dummy die is buried in a fan-out region. FIG. 1B is a plan view taken along a cut line I-I′ of FIG. 1A.

Referring to FIG. 1A, a main die 120 is disposed within a cavity 130h, and is sealed by a sealing material 130. Dummy structures 140 are disposed within cavities 135h, and are sealed by a sealing material 135. An insulating layer 110 and conductive vias 112 penetrating the insulating layer 110 may be provided.

Referring to FIG. 1B, the main die 120 is disposed within the cavity 130h provided at a center, and four dummy structures 140 are buried within the cavities 135h which are provided around the main die 120 to suppress generation of the warpage in a reflow process.

However, when a larger dummy structure 140 is used to suppress the warpage, an area in which the conductive vias 112 can be provided is reduced. As a result, the signal transmission path vertically penetrating through the fan-out semiconductor package is limited.

The above information disclosed in this Background section is only for enhancement of understanding of the background of the disclosure, and therefore it may contain information that does not form the prior art that is already known to a person of ordinary skill in the art.

### SUMMARY

Some example embodiments of the present disclosure provide fan-out semiconductor packages and/or methods for manufacturing the fan-out semiconductor package capable of providing a signal transmission path vertically penetrating in a fan-out region while suppressing warpage using a dummy die.

According to a first aspect of the present disclosure, a fan-out semiconductor package includes a substrate including a cavity, one or more semiconductor dies within the cavity, the one or more semiconductor dies including a plurality of connection terminals at a bottom surface thereof, one or more dummy dies at a fan-out region within the cavity, the one or more dummy dies including a plurality of through silicon vias (TSVs), a filler filling an empty space within the cavity, a lower redistribution layer on bottom surfaces of the substrate, the one or more semiconductor dies, and the one or more dummy dies, the lower redistribution layer electrically connected to at least some of the plurality of connection terminals of the one or more semiconductor dies and the plurality of through silicon vias of the one or more dummy dies, and an upper redistribution layer on top surfaces of the substrate, the one or more semiconductor dies, and the one or more dummy dies, the upper redistribution layer electrically connected to the plurality of through silicon vias of the one or more dummy dies.

According to a second aspect of the present disclosure, a fan-out semiconductor package includes a lower redistribution layer, a plurality of solder bumps on a bottom surface of the lower redistribution layer, one or more semiconductor dies on an top surface of the lower redistribution layer, one or more dummy dies on the top surface of the lower redistribution layer at a region where the one or more semiconductor dies are not disposed, the one or more dummy dies each including a plurality of through silicon vias, an upper redistribution layer across first top surfaces of the one or more semiconductor dies and second top surfaces of the one or more dummy dies, and a mold material filling an empty space between the lower redistribution layer and the upper redistribution layer, wherein the upper redistribution layer and the lower redistribution layer are electrically connected through at least some of the plurality of through silicon vias.

According to a third aspect of the present disclosure, a method for manufacturing a fan-out semiconductor package includes fixing a substrate on a carrier, the substrate having a quadrangle frame shape and including a cavity, attaching a semiconductor die at a center of the cavity so that a bottom surface of the semiconductor die, at which a plurality of connection terminals are provided, is in contact with the carrier, attaching a plurality of dummy dies, each of which including a plurality of through silicon vias to a remaining region within the cavity where the semiconductor die is not disposed, filling an empty space within the cavity with a filler by supplying the filler from an upper portion of the cavity, grinding top surfaces of the substrate, the semiconductor die, and the plurality of dummy dies to expose the plurality of through silicon vias of the plurality of dummy dies, providing an upper redistribution layer on the top surfaces of the substrate, the semiconductor die, and the plurality of dummy dies such that the upper redistribution layer is electrically connected to at least some of the plurality of through silicon vias of the plurality of dummy dies, providing a lower redistribution layer on bottom surfaces of the substrate, the semiconductor die, and the plurality of dummy dies such that the lower redistribution layer is electrically connected to at least some of the plurality of connection terminals of the semiconductor die and the plurality of through silicon vias of the plurality of dummy dies, and providing a plurality of solder bumps on a bottom surface of the lower redistribution layer.

The example embodiments of the present disclosure may use a dummy die with through silicon vias while suppressing warpage in a reflow process by disposing the dummy die in a fan-out region so that a plurality of signal transmission paths vertically penetrating a semiconductor package are secured. Advantageous effects by the present disclosure will be described once again in in conjunction with the example embodiments in the following description.

### BRIEF DESCRIPTION OF THE DRAWINGS

FIG. 1A is a cross-sectional view of a fan-out semiconductor package including a dummy die according to a conventional art.

FIG. 1B is a plan view taken along a cut line I-I′ of FIG. 1A.

FIG. 2A is a cross-sectional view of a fan-out semiconductor package according to an example embodiment of the present disclosure.

FIG. 2B is a plan view taken along a cut line II-II′ of FIG. 2A.

FIGS. 3A to 3C are process diagrams schematically illustrating a method of manufacturing a fan-out semiconductor package according to an example embodiment of the present disclosure.

FIG. 4A is a cross-sectional view of a fan-out semiconductor package according to an example embodiment of the present disclosure.

FIG. 4B is a plan view taken along a cut line II-II′ of FIG. 4A.

FIG. 4C is a plan view of a substrate illustrated in FIG. 4B.

FIG. 4D is a plan view of a fan-out semiconductor package according to an example embodiment using the substrate shown in FIG. 4C.

FIG. 5A is a cross-sectional view of a fan-out semiconductor package according to an example embodiment of the present disclosure.

FIG. 5B is a plan view taken along a cut line IV-IV′ of FIG. 5A.

FIG. 6A is a plan view of a fan-out semiconductor package according to an example embodiment of the present disclosure.

FIG. 6B is a plan view of a substrate illustrated in FIG. 6A.

FIG. 7 is a plan view of a fan-out semiconductor package according to an example embodiment of the present disclosure.

FIG. 8 is a cross-sectional view of a 3D fan-out semiconductor package according to an example embodiment of the present disclosure.

FIG. 9 is a cross-sectional view of a fan-out semiconductor package according to an example embodiment of the present disclosure.

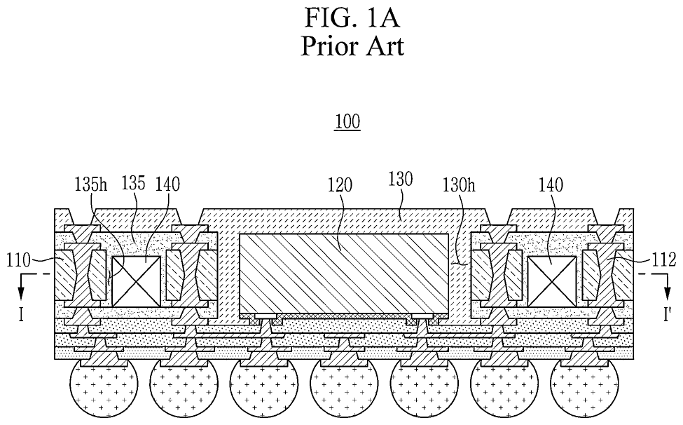

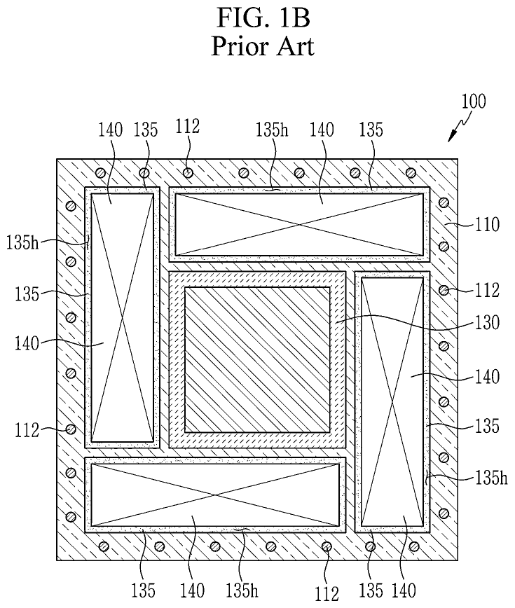

### DETAILED DESCRIPTION

Hereinafter, some example embodiment of the present disclosure will be described more fully with reference to the accompanying drawings for a person of ordinary skill to easily implement the present disclosure. As those skilled in the art would realize, the described example embodiments may be modified in various different ways, all without departing from the spirit or scope of the present disclosure. Accordingly, the drawings and description are to be regarded as illustrative in nature and not restrictive. Like reference numerals designate like elements throughout the specification.

In addition, since size and thickness of each component shown in the drawings are arbitrarily shown for convenience of description, the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

While the term “same,” “equal” or “identical” is used or a specific number is recited in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

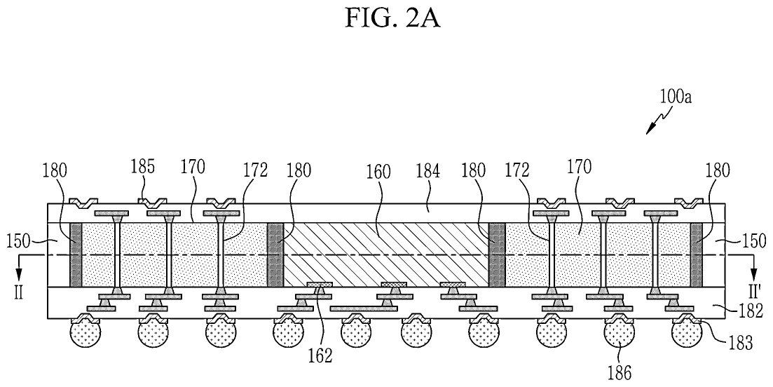

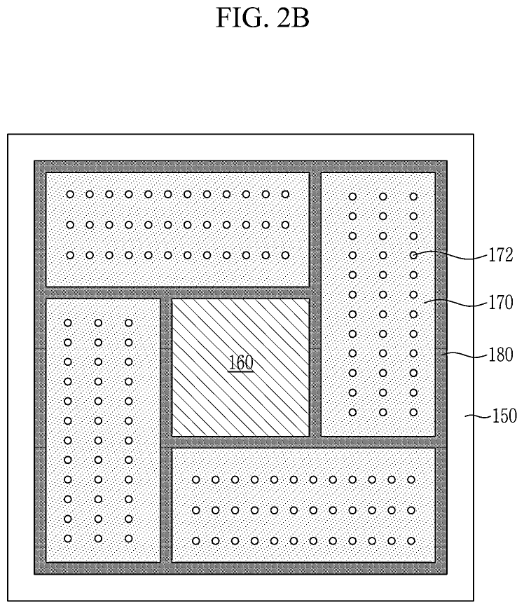

FIG. 2A is a cross-sectional view of a fan-out semiconductor package 100a according to an example embodiment of the present disclosure, and FIG. 2B is a plan view taken along a cut line II-II′ of FIG. 2A.

Referring to FIG. 2A, the fan-out semiconductor package 100a includes a semiconductor die 160, dummy dies 170, a substrate 150, an upper redistribution layer 184, a lower redistribution layer 182, and solder bumps 186.

A plurality of connection terminals 162 are provided at one surface of the semiconductor die 160. The plurality of connection terminals 162 are electrically connected to the lower redistribution layer 182. In the present disclosure, the semiconductor die may be an integrated circuit (IC). The integrated circuit includes a CPU, a GPU, an FPGA, a digital signal processor, an encryption processor, a microprocessor, a microcontroller, an AP, an ASIC, a DRAM, a flash memory, or the like, but the present disclosure is not limited thereto.

A plurality of through silicon vias (TSVs) 172 are provided in the dummy dies 170, which are disposed side by side around the semiconductor die 160. The lower redistribution layer 182 is electrically connected to at least some of the plurality of through silicon vias 172 of the dummy dies 170.

The dummy dies 170 may be manufactured based on silicon similarly to the semiconductor die 160. The dummy dies 170 may not have an element for performing a specific function, but may provide a signal transmission path penetrating in a thickness direction by the plurality of through silicon vias 172 provided therein. In the present disclosure, the word “dummy” means that it is made of a material similar to that of the semiconductor die but does not include an element other than the through silicon via (TSV). In addition, in the present disclosure, the word “dummy die” refers to a die including only the TSV unless explicitly referred to as a dummy die that does not even include the TSV.

A filler 180 fills empty spaces between the semiconductor die 160 and the dummy dies 170 and between the dummy dies 170 and the substrate 150. The filler 180 bonds and fixes the semiconductor die 160, the dummy dies 170, and the substrate 150 to each other. A material of the filler 180 is not limited. For example, a resin material such as an epoxy or a polyimide may be used, and an improved material such as a prepreg, an Ajinomoto Build-up Film (ABF), FR-4, bismaleimide trizaine (BT), or the like may also be used.

A plurality of connection terminals 183 are provided on a bottom surface of the lower redistribution layer 182, and the solder bumps 186 are provided on the plurality of connection terminals 183. The solder bumps 186 of the fan-out semiconductor package 100a is melt-bonded to a corresponding connection terminals of another device (e.g., a system substrate) by a reflow process. In the reflow process, because the semiconductor die 160 and the dummy dies 170 occupy a larger area than the substrate 150, generation of warpage is minimized.

The upper redistribution layer 184 is provided on top surfaces of the semiconductor die 160, the dummy die 170, and the substrate 150. The upper redistribution layer 184 is electrically connected to at least some of the plurality of through silicon vias 172 of the dummy dies 170. A plurality of connection terminals 185 are provided on a top surface of the upper redistribution layer 184. The connection terminals 185, the upper redistribution layer 184, the through silicon vias 172, the lower redistribution layer 182, the connection terminals 183, the solder bumps 186, and the connection terminals 162 may be electrically connected according to design of connection layers inside the upper redistribution layer 184 and the lower redistribution layer 182.

In FIG. 2A, thicknesses of the semiconductor die 160 and the dummy dies 170 are shown to be the same, but the present disclosure is not necessarily limited thereto. A thickness of the semiconductor die 160 may be smaller than a thickness of the dummy dies 170. In this case, the filler 180 may cover a top surface of the semiconductor die 160 to planarize the top surface of the package. Conversely, the thickness of the dummy dies 170 may be less than that of the semiconductor die 160. In this case, an insulating layer including a conductive via electrically connected to at least some of the plurality of through silicon vias 172 of the dummy dies 170 may be provided on the dummy die 170.

Referring to FIG. 2B, the substrate 150 includes a cavity, and the semiconductor die 160 and the dummy dies 170 are disposed within the cavity. The dummy dies 170 includes the plurality of through silicon vias 172.

In the present example embodiment, the semiconductor die 160 is disposed at a center (or a central portion) of the cavity, and four dummy dies 170 are disposed at or along a periphery of the cavity. The number of dummy dies 170 is not limited. It is possible to use more or fewer dummy dies. The number of through silicon vias 172 included in each dummy die is not limited, and not all dummy dies need to include the same number of through silicon vias 172. If the warpage is suppressed and the signal transmission path penetrating the fan-out semiconductor package 100a in a vertical direction is provided, the number and shapes of dummy dies, and the number and dispositions of through silicon vias may be appropriately set according to design.

In the present example embodiment, the fan-out semiconductor package 100a including one semiconductor die 160 is disclosed, but a plurality of semiconductor dies may be disposed. Further, if a sufficient number of through silicon vias are secured in accordance with design needs, some of the plurality of dummy dies may not include any through silicon via.

The number and disposition positions of the dummy dies 170 may be determined to have a shape in which a region according to an outermost contour including the semiconductor die and the dummy dies is symmetrical with respect to a line passing through a center point on a plane of the fan-out semiconductor package.

That is, when the cavity has a square shape or the semiconductor die has a rectangular shape (or an oblong shape) occupying about half of the cavity, a rectangular dummy die occupying about half of the cavity may be disposed side by side with the semiconductor die. In some example embodiments, when the semiconductor die has a rectangular shape that occupies two third of the cavity, one dummy die that occupies two third of the cavity may be disposed side by side with the semiconductor die, or two dummy dies, each of which occupies one sixth of the cavity, may be disposed side by side with the semiconductor die. As described above, the number and sizes of dummy dies may be flexibly determined according to a disposition of the semiconductor die. When a region according to the outermost contour including the semiconductor die and the dummy die has an asymmetrical shape, warpage is likely to occur unevenly in the reflow process, and the warpage may lead to a problem of poor contact.

In FIG. 2B, disclosed is a configuration in which four dummy dies 170 have the same size and have the same number and dispositions of through silicon vias 172. When the dummy die having the same structure is used, efficient mass production of the dummy die is possible. In addition, when the dummy die is formed in a quadrangle shape (that is, when the dummy die is set to a shape similar to that of the semiconductor die), it is easy to manufacture a plurality of dummy dies at a wafer level.

In addition, if each dummy die has the same number and dispositions of through silicon vias, it helps efficient mass production of dummy dies. Since it is possible to design using only some of the plurality of through silicon vias of each dummy die as desired, the dummy die may be used in various packages.

As illustrated in FIG. 2B, the semiconductor die 160 and the dummy dies 170 are disposed to minimize an empty space within the cavity of the substrate 150. If the empty space within the cavity is large, a possibility of occurrence of warpage becomes high. In addition, by minimizing the empty space in the cavity, it becomes easy to determine positions of the semiconductor die 160 and the dummy dies 170 when the semiconductor die 160 and the dummy dies 170 are disposed within the cavity.

In some example embodiments, a planar area occupied by the semiconductor die 160 and the plurality of dummy dies 170 may be set to be 90% or more of a total planar area of the cavity. In addition, the total planar area of the cavity may be set to be 80% or more of an area according to an outermost contour of the substrate 150.

Because the through silicon vias 172 are provided in the dummy dies 170 in the present example embodiment, an electrical path such as a conductive via vertically penetrating does not need to be provided in the substrate 150. Because a process for providing the electrical path such as the conductive via at the substrate 150 is not desired, overall complexity of a manufacturing process is reduced.

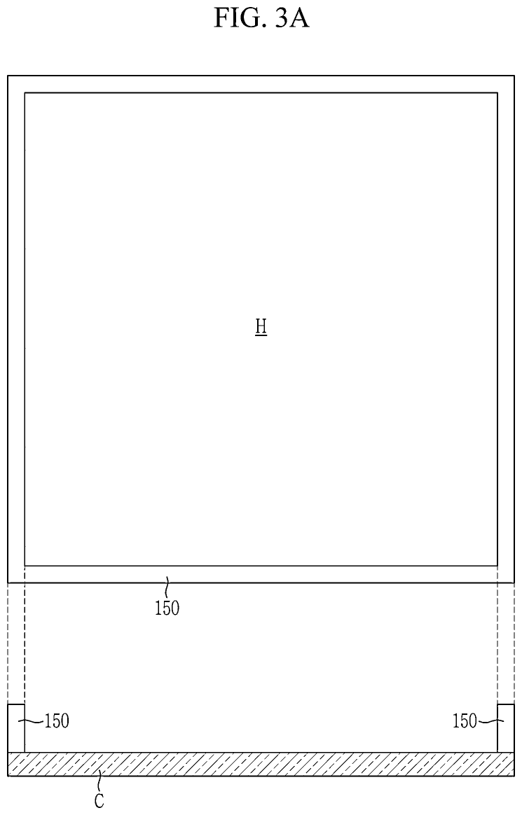

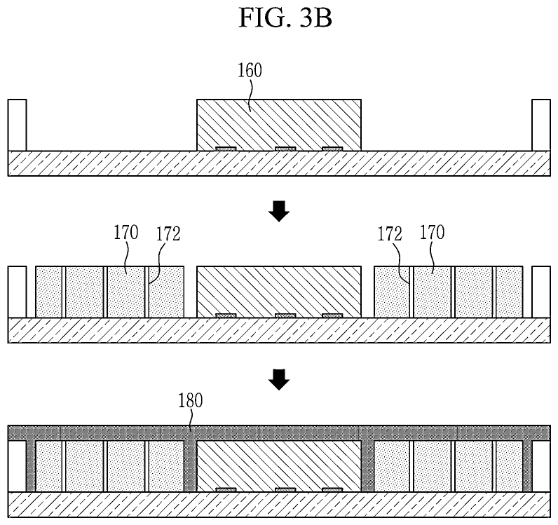

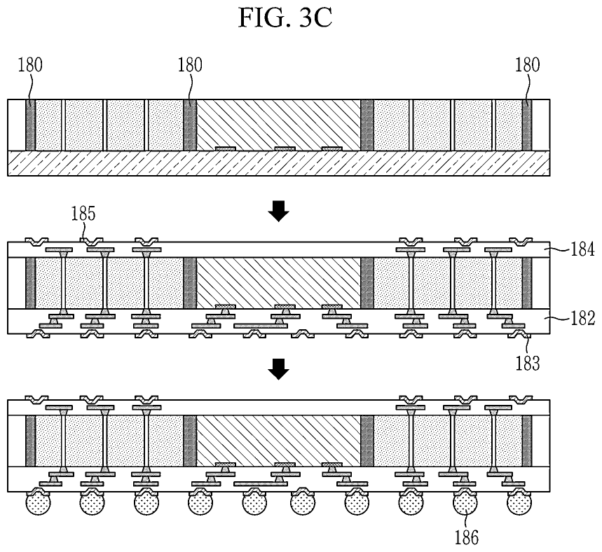

FIGS. 3A to 3C are process diagrams schematically illustrating a method for manufacturing the fan-out semiconductor package 100a according to an example embodiment of the present disclosure.

Referring to FIG. 3A, first, a quadrangle frame-shaped substrate 150 having a cavity H is prepared. This substrate 150 is fixed on a carrier C.

For example, the cavity H may be provided using a laser drill, a mechanical drill, sand blasting, or the like. However, the present disclosure is not limited thereto.

Then, the semiconductor die 160 is disposed at a center of the cavity H. For example, the semiconductor die 160 may be attached to the carrier C through an adhesive, an adhesive film, or the like. The semiconductor die 160 includes one surface on which the plurality of connection terminals are provided. The one surface of the semiconductor die 160 is disposed to face downward.

Next, the plurality of dummy dies 170 having the plurality of through silicon vias 172 are disposed around the semiconductor die 160. For example, the dummy dies 170 may also be attached to the carrier C through an adhesive, an adhesive film, or the like. A region at which the plurality of dummy dies 170 are disposed is a fan-out region.

Next, the filler 180 is supplied, and the filler fills empty spaces between the semiconductor die 160 and the plurality of dummy dies 170 and between the plurality of dummy dies 170 and the substrate 150.

After the filler is cured, a top surface of the cured filler is planarized by grinding or the like. The planarization is not necessarily required. However, in order to use at least some of the plurality of through silicon vias 172 of the dummy dies 170 as the signal transmission paths, the at least some of the through silicon vias 172 have to be exposed at the top surface of the dummy dies 170.

Then, the upper redistribution layer 184 and the lower redistribution layer 182 are respectively provided on the top and bottom surfaces of the substrate 150, the semiconductor die 160, and the plurality of dummy dies 170. The plurality of connection terminals 185 and 183 are provided on the top surface of the upper redistribution layer 184 and the bottom surface of the lower redistribution layer 182.

Then, a plurality of solder bumps 186 are provided on the connection terminals 183 of the lower redistribution layer 182. When the fan-out semiconductor package 100a is mounted at the system substrate or the like, the solder bumps 186 are melt-bonded to connection terminals provided on a surface of the system substrate or the like by the reflow process.

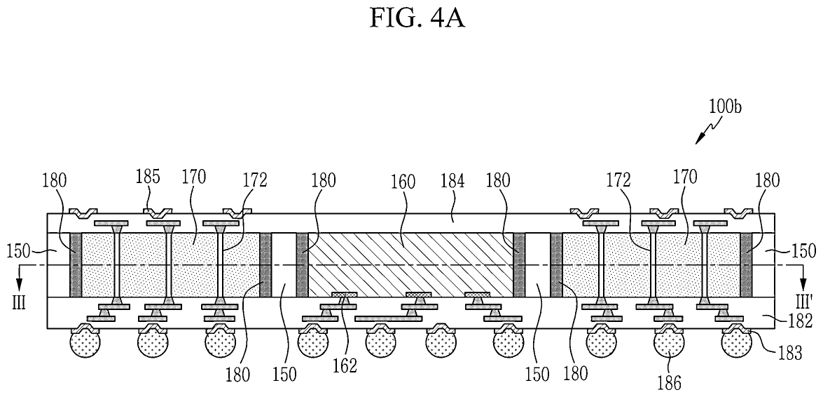

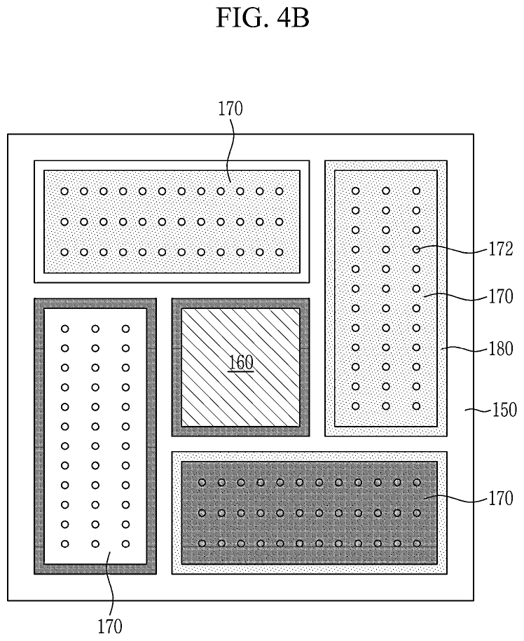

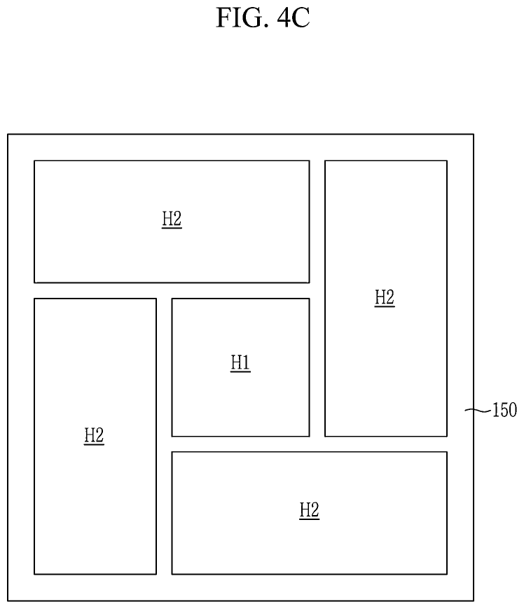

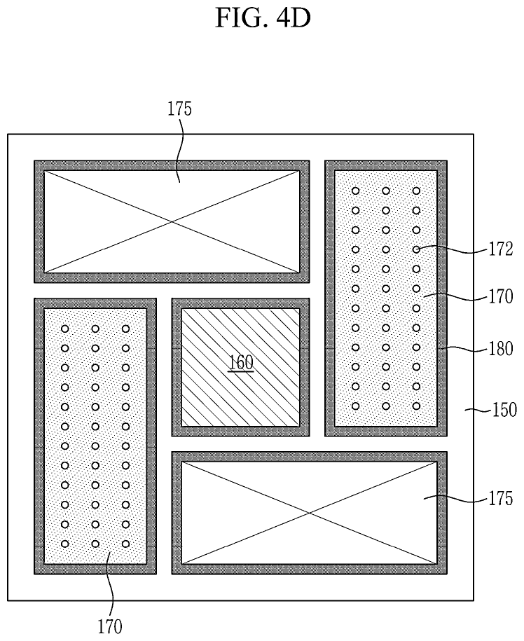

FIG. 4A is a cross-sectional view of a fan-out semiconductor package 100b according to an example embodiment of the present disclosure, FIG. 4B is a plan view taken along a cut line II-II′ of FIG. 4A, and FIG. 4C is a plan view of a substrate illustrated in FIG. 4B.

Referring to FIG. 4A, the fan-out semiconductor package 100b includes the semiconductor die 160, the dummy dies 170, the substrate 150, the upper redistribution layer 184, the lower redistribution layer 182, and the solder bump 186. Because these configurations are substantially the same as those of the fan-out semiconductor package 100a illustrated in FIG. 2A, a detailed description of these configurations may refer to the description of the fan-out semiconductor package 100a illustrated in FIG. 2A. Accordingly, hereinafter, only a difference between the fan-out semiconductor package 100b according to the present example embodiment and the fan-out semiconductor package 100a shown in FIG. 2A will be described.

As illustrated in FIG. 4A, in the fan-out semiconductor package 100b according to the present example embodiment, there is a portion of the substrate 150 between the semiconductor die 160 and the dummy dies 170. That is, a cavity for the semiconductor die 160 and a cavity for each dummy die 170 are separately provided.

Referring to FIG. 4B, it may be seen that a total of five cavities are provided for one semiconductor die 160 and four dummy dies 170. The filler 180 is filled in an empty space to surround the semiconductor die 160 or each dummy die 170 within each cavity.

For ease of understanding, FIG. 4C shows a plan view of the substrate 150. A cavity H1 for the semiconductor die 160 is provided at a center of the substrate 150, and four cavities H2 for the dummy dies 170 are provided around the cavity H1.

By providing cavities for the semiconductor die 160 and each dummy die 170, a position of each die may be easily determined. The dummy dies 170 includes the plurality of through silicon vias 172, and at least some of the plurality of through silicon vias 172 are electrically connected to the upper redistribution layer 184 and the lower redistribution layer 182. In order to implement this electrical connection without a defect, determining of an accurate position of the dummy die 170 is desired. By individually providing the cavities H1 and H2 for each of the dies 160 and 170, it a position of each die may be easily determined.

Because the fan-out semiconductor package 100a illustrated in FIG. 2A uses the substrate 150 having one large cavity, it is relatively easy to manufacture the substrate 150 having such one large cavity, but it is relatively difficult to determine a position of each die. On the other hand, in the fan-out semiconductor package 100b according to the present example embodiment, it is relatively complicated to form a plurality of cavities at the substrate 150, but a position of each die may be easily determined.

On the other hand, FIG. 4D is a plan view of a fan-out semiconductor package according to another embodiment using the substrate shown in FIG. 4C.

In the above-described embodiments (e.g., FIG. 4B), four dummy dies 170 are used, and all dummy dies 170 have the plurality of through silicon vias 172. However, it will be understood by those skilled in the art that it is possible to use the dummy die 170 with the through silicon vias 172 and a dummy die 175 without the through silicon via together.

Referring to FIG. 4D, the dummy dies 170 having the through silicon vias 172 are disposed in two cavities of four cavities H2 for the dummy dies, and the dummy dies 175 without the through silicon via are disposed in the other two cavities.

The number of dummy dies 170 with the through silicon vias 172 and the number of dummy dies 175 without the through silicon via may be adjusted according to design needs. In addition, positions of the dummy die 170 and the dummy die 175 may be adjusted according to design needs. That is, the number and a position of the dummy die 170 and the number and a position of the dummy die 175 may be determined according to a design of an entire package.

Both the dummy die 170 and the dummy die 175 may be silicon-based dies, and the dummy die 170 with the through silicon vias 172 and the dummy die 175 without the through silicon via may have the same or substantially similar effect in terms of suppressing warpage.

It will be easily understood by those skilled in the art that in FIG. 4D, the cavity is individually provided for each die, but as shown in FIG. 2B, it is possible to dispose the semiconductor die 160, the dummy die 170 with the through silicon vias 172, and the dummy die 175 without the through silicon via in one cavity.

In some example embodiments, all of the plurality of dummy dies 170 may have the through silicon vias 172 for convenience of description. In some other example embodiments, some of the dummy dies 170 may be replaced with the dummy die 175 without the through silicon via.

In addition, the dummy die 170 and the dummy die 175 may have the same size or different sizes. When the dummy die 175 having a different size from that of the dummy die 170 is used, the cavity for the dummy die 175 has a different size from that of the cavity for the dummy die 170 in FIG. 4D.

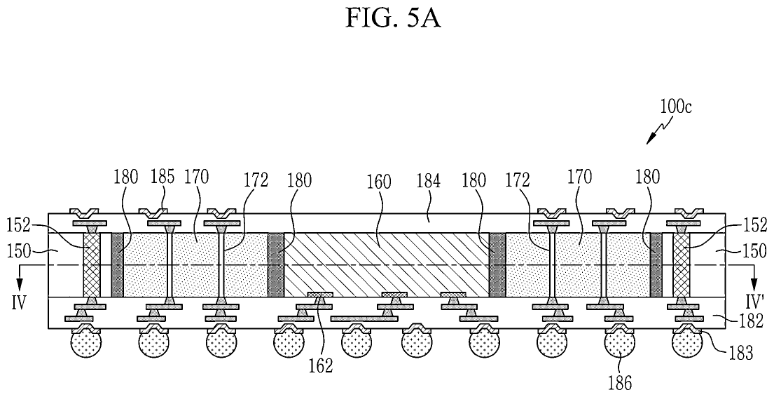

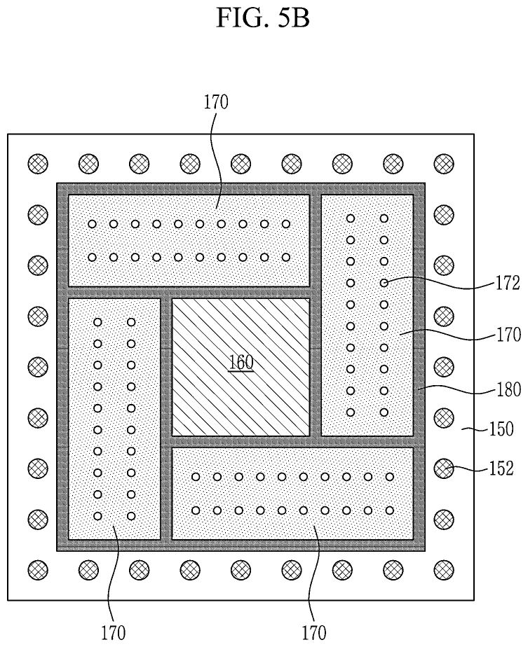

FIG. 5A is a cross-sectional view of a fan-out semiconductor package 100c according to an example embodiment of the present disclosure, and FIG. 5B is a plan view taken along a cut line IV-IV′ of FIG. 5A.

Referring to FIG. 5A, the fan-out semiconductor package 100b includes the semiconductor die 160, the dummy dies 170, the substrate 150, the upper redistribution layer 184, the lower redistribution layer 182, and the solder bump 186. Because these configurations are substantially the same as those of the fan-out semiconductor package 100a illustrated in FIG. 2A, a detailed description of these configurations may refer to the description of the fan-out semiconductor package 100a illustrated in FIG. 2A. Accordingly, hereinafter, only a difference between the fan-out semiconductor package 100c according to the present example embodiment and the fan-out semiconductor package 100a shown in FIG. 2A will be described.

As shown in FIG. 5A, in the fan-out semiconductor package 100c according to the present example embodiment, conductive vias 152 are additionally provided in the substrate 150. The conductive vias 152 provide signal transmission paths vertically penetrating the substrate 150. The conductive vias 152 may be a conductive material filling holes penetrating the substrate 150 or a conductive material plated on a side wall of the holes. At least some of a plurality of conductive vias 152 are electrically connected to the upper redistribution layer 184 and/or the lower redistribution layer 182.

Referring to FIG. 5B, the plurality of conductive vias 152 are provided along an edge of the substrate 150. The semiconductor die 160 and four dummy dies 170 are disposed within a cavity of the substrate 150, and an empty space in the cavity is filled with the filler 180.

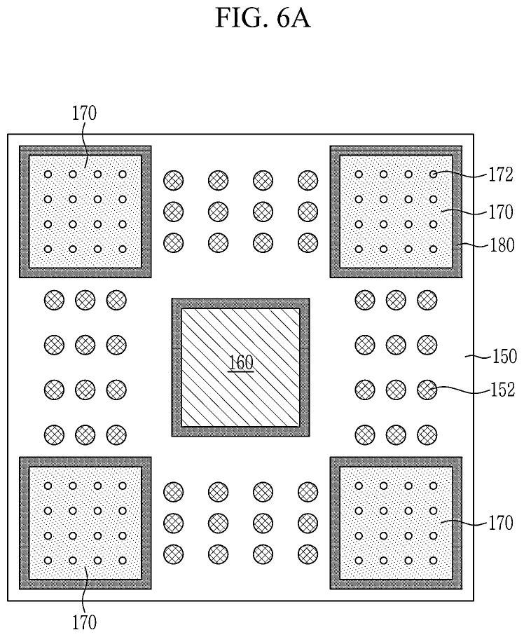

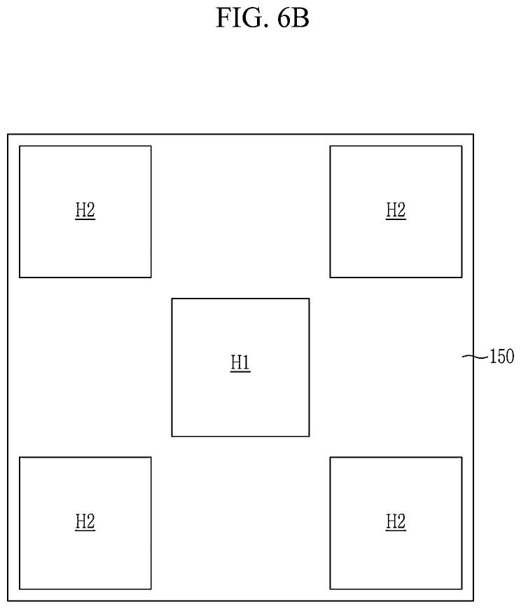

The conductive vias 152 provided in the substrate 150 provide the signal transmission paths together with the plurality of through silicon vias 172 of the dummy dies 170. In the present example embodiment, the conductive vias 152 are provided along the edge of the substrate 150, but the distribution of the conductive vias 152 may be adjusted according to dispositions of the semiconductor die 160 and the dummy dies 170. FIGS. 6A and 6B illustrate another disposition example of the conductive via 152 and the dummy dies 170.

Referring to FIG. 6A, four dummy dies 170 are disposed at corners of the substrate 150, respectively, and the conductive vias 152 are provided in a region between the dummy dies 170. A configuration of the cavities of the substrate 150 is illustrated in FIG. 6B.

As shown in FIG. 6B, a cavity H1 for the semiconductor die 160 is provided at a center (or a central portion) of the substrate 150, and a cavities H2 for the dummy dies are provided at corners of the substrate 150.

As described above, warpage occurs most frequently near a corner of a quadrangle substrate. By disposing the dummy dies 170 at corners of the substrate 150, the warpage generated at the corner may be suppressed. However, it will be understood by those skilled in the art that a disposition of the dummy dies 170 and a disposition of the conductive vias 152 may be changed according to design.

In the above-described example embodiments, an example in which one semiconductor die 160 is disposed at a center (or a central portion) of the package or at a center of the cavity and four dummy dies 170 are disposed around the semiconductor die 160 is used. However, the present disclosure is not limited thereto.

In some example embodiments, the semiconductor die may be disposed at an edge of the package or at an edge of the cavity rather than at the center of the package or at the center of the cavity. As an example, in FIG. 2B, the semiconductor die may be disposed near a corner of the cavity. As another example, in FIG. 4B, a cavity for the semiconductor die may be provided near a corner of the substrate 150. In this case, the dummy dies 170 do not need to surround the semiconductor die and be disposed around the semiconductor die. In the example of FIG. 2B, when the semiconductor die is disposed near the corner of the cavity, the dummy dies may be disposed in a remaining region of the cavity. In the example of FIG. 4B, when the cavity for the semiconductor die is provided near the corner of the substrate, a cavity for the dummy dies may be provided near remaining corners of the substrate and/or at a center of the substrate.

In addition, a different number of dummy dies may be used according to design. In the above-described example embodiments, four dummy dies are used, but eight dummy dies may be disposed around the semiconductor die.

In addition, dummy dies of different sizes may be used according to design. In the above-described example embodiments, four dummy dies having the same size are used, but for example, dummy dies having a relatively long length may be disposed at an upper side and a lower side of the semiconductor die, respectively, and dummy dies having a relatively short length may be disposed at a left side and a right side of the semiconductor die, respectively. When dummy dies having different structures are used, flexibility and usability of design may be increased. On the other hand, as described above, when the dummy dies having the same size are used, manufacturing efficiency of the dummy dies may be increased.

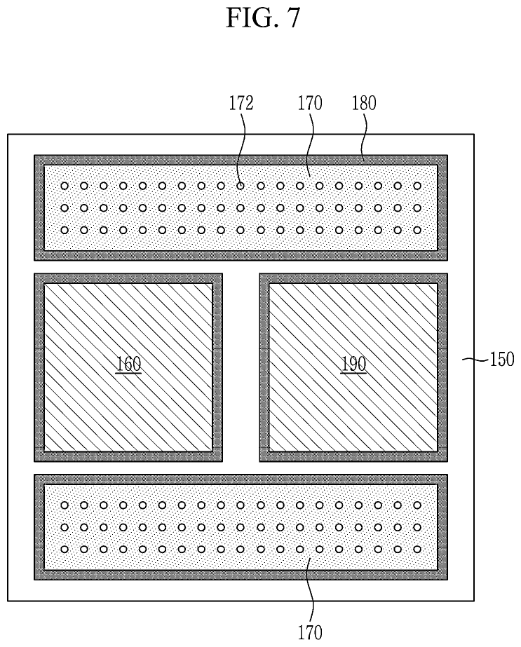

FIG. 7 illustrates an example of a fan-out semiconductor package including two semiconductor dies 160 and 190. The two semiconductor dies 160 and 190 may be of the same type or different types, but the present disclosure is not limited thereto. For example, each of the two semiconductor dies 160 and 190 may be the same type of memory semiconductor. In some example embodiments, the semiconductor die 160 may be a non-memory semiconductor, and the semiconductor die 190 may be a memory semiconductor.

In the present example embodiment, the two semiconductor dies 160 and 190 are disposed side by side. To this end, the substrate 150 includes two cavities for two semiconductor dies. Two dummy dies 170 with the plurality of through silicon vias 172 are disposed at upper and lower sides, respectively, while facing both of the two semiconductor dies 160 and 190.

In the present example embodiment, four cavities are provided in the substrate 150. However, it is possible to dispose the two semiconductor dies 160 and 190 and the two dummy dies 170 in one cavity. In another example embodiment, a substrate having one cavity accommodating the two semiconductor dies 160 and 190 and two cavities accommodating each dummy die 170 may be used. In another example embodiment, two semiconductor dies may be disposed along a lower edge of the substrate, and one dummy die may be disposed along an upper edge of the substrate.

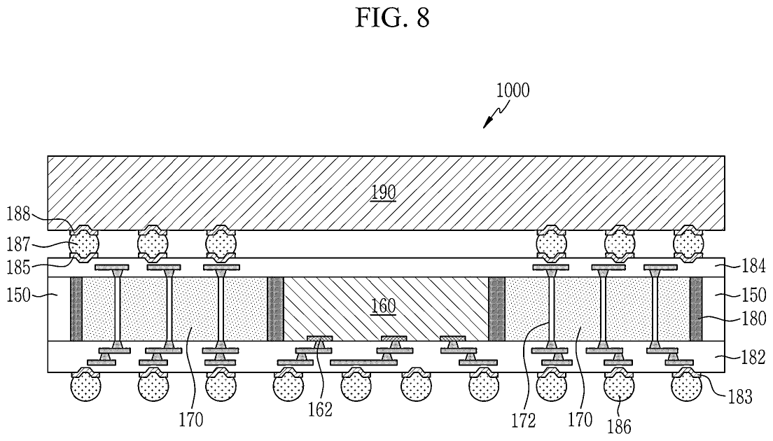

FIG. 8 is a cross-sectional view of a 3D fan-out semiconductor package 1000 according to an example embodiment of the present disclosure.

The 3D fan-out semiconductor package 1000 according to the present example embodiment includes two semiconductor dies 160 and 190, and the additional semiconductor die 190 is stacked above or on the semiconductor die 160.

The 3D fan-out semiconductor package 1000 has a configuration in which the additional semiconductor die 190 is stacked above or on the fan-out semiconductor package 100a illustrated in FIG. 2A. Because configurations of the semiconductor die 160, the dummy dies 170, the filler 180, the lower redistribution layer 182, the upper redistribution layer 184, and the solder bumps 186 are the same as those of the fan-out semiconductor package 100a shown in FIG. 2A, descriptions of these configurations will be omitted.

In the present example embodiment, a plurality of connection terminals 185 provided on a top surface of the upper redistribution layer 184 are connected with a plurality of connection terminals 188 provided on a bottom surface of the additional semiconductor die 190 through a plurality of solder bumps 187.

In the present example embodiment, the semiconductor die 160 and the additional semiconductor die 190 may be the same type of semiconductor or different types of semiconductors. For example, the semiconductor die 160 may be a non-memory semiconductor, and the additional semiconductor die 190 may be a memory semiconductor.

For simplicity of explanation, the structure in which the additional semiconductor die 190 is stacked above or on a top surface of the fan-out semiconductor package 100a shown in FIG. 2A is used, but it will be easily understood by those skilled in the art that the additional semiconductor die 190 is stacked above or on top surfaces of the fan-out semiconductors shown in FIGS. 4 to 7.

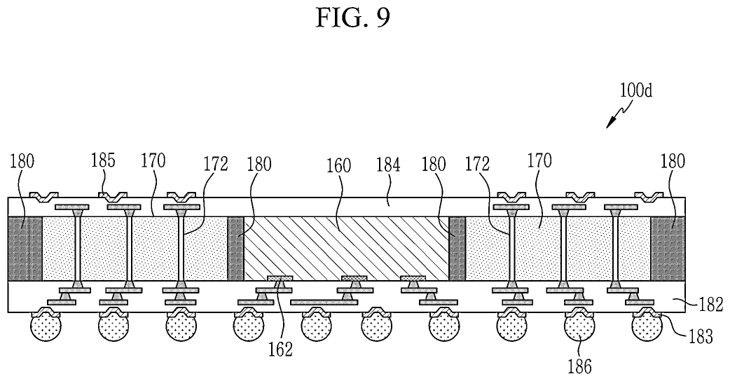

FIG. 9 is a cross-sectional view of a fan-out semiconductor package according to an example embodiment of the present disclosure.

In the above-described embodiments, the fan-out semiconductor package includes the substrate having the cavity. The substrate having the cavity may be a panel, and thus the fan-out semiconductor package described above may be manufactured by panel level packaging. In the present example embodiment, the fan-out semiconductor package that may be manufactured by wafer-level packaging (WLP) is disclosed.

Referring to FIG. 9, the fan-out semiconductor package 100d includes the semiconductor die 160, the dummy dies 170, the upper redistribution layer 184, the lower redistribution layer 182, and the solder bumps 186. Because these configurations are substantially the same as those of the fan-out semiconductor package 100a illustrated in FIG. 2A, descriptions of these configurations will be omitted. A difference between the fan-out semiconductor package 100a shown in FIG. 2A and the fan-out semiconductor package 100d of the present example embodiment will be mainly described.

The fan-out semiconductor package 100d does not include the substrate 150 having the cavity. A periphery of the semiconductor die 160 and a periphery of the dummy dies 170 may be filled with the filler 180, and the filler 180 may be a molding material. Because the TSVs 172 provided within the dummy dies 170 replace Cu posts, it is not desired to separately generate the Cu posts. The upper redistribution layer 184 and the lower redistribution layer 182 are electrically connected only through at least some of the through silicon vias of the dummy dies 170.

The number of semiconductor dies 160 and the number of dummy dies 170 are not limited to the present example embodiment. The fan-out semiconductor package 100d may include one or more semiconductor dies 160 and one or more dummy dies 170. A planar area occupied by one or more semiconductor dies 160 and one or more dummy dies 170 may be 80% or more of a total planar area of the lower redistribution layer 182 so that overall rigidity of the package is increased.

The fan-out semiconductor package 100d may be manufactured by wafer level packaging technology. In this case, since a process for providing a copper (Cu) post is not desired, a manufacturing process is simplified. In particular, when a height (a thickness) of the semiconductor die is large, it is very difficult to form the copper (Cu) post in a wafer level packaging process. This is because a height of a structure that may be provided by photolithography and etching processes is limited. By using the dummy die including the through silicon via, a complexity of a process according to the height (the thickness) of the semiconductor die may be reduced or ignored.

A method for disposing the semiconductor die and the dummy die, the number of semiconductor dies and the number of dummy dies are not limited in the fan-out semiconductor package 100d. In the above-described example embodiments, the method for disposing the semiconductor die and the dummy die may also be applied to the fan-out semiconductor package 100d of the present example embodiment. Because the substrate having the cavity is not used, disposition positions and the number of semiconductor dies and disposition positions and the number of dummy dies may be more flexibly designed.

While this disclosure has been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims.

For example, although the plurality of connection terminals 162 are provided only on a bottom surface of the semiconductor die 160 in the above-described example embodiments, a plurality of connection terminals may also be provided on a top surface of the semiconductor die 160. In addition, the semiconductor die 160 includes a plurality of through silicon vias. Accordingly, the plurality of through silicon vias may provide signal transmission paths to an element stacked above or on the plurality of through silicon vias.

In addition, in the above-described example embodiments, the package includes the upper redistribution layer 184, but the upper redistribution layer 184 may be omitted. When the additional semiconductor die 190 stacked above or on the package includes a semiconductor layer and a redistribution layer, the redistribution layer of the additional semiconductor die may replace the upper redistribution layer 184.

In addition, in the above-described example embodiments, the solder bumps 186 and 187 are used for connection between elements, but a technique of providing a bump above or on a Cu pillar may be used for connection between the elements.

What is claimed is:

1. A fan-out semiconductor package, comprising:
a substrate including a cavity;
one or more semiconductor dies within the cavity, the one or more semiconductor dies including a plurality of connection terminals at a bottom surface thereof;
one or more dummy dies at a fan-out region within the cavity, the one or more dummy dies including a plurality of through silicon vias (TSVs);
a filler filling an empty space within the cavity;
a lower redistribution layer on bottom surfaces of the substrate, the one or more semiconductor dies, and the one or more dummy dies, the lower redistribution layer electrically connected to the plurality of connection terminals of the one or more semiconductor dies and at least some of the plurality of through silicon vias of the one or more dummy dies; and
an upper redistribution layer on top surfaces of the substrate, the one or more semiconductor dies, and the one or more dummy dies, the upper redistribution layer electrically connected to at least some of the plurality of through silicon vias of the one or more dummy dies.

2. The fan-out semiconductor package of claim 1, wherein the substrate includes the cavity accommodating the one or more semiconductor dies and the one or more dummy dies, and a region according to an outermost contour including the one or more semiconductor dies and the one or more dummy dies, the region being symmetrical with respect to a center point of the fan-out semiconductor package.

3. The fan-out semiconductor package of claim 2, wherein the cavity has a quadrangle shape and a center point of the quadrangle shape coincides with the center point of the fan-out semiconductor package, the one or more semiconductor dies are at a central portion within the cavity and four dummy dies having a rectangular shape are at a periphery of the semiconductor die such that a long side of one of the four dummy dies and a short side of another of the four dummy dies face each side of the cavity.

4. The fan-out semiconductor package of claim 2, wherein the cavity has a quadrangle shape and a center point of the quadrangle shape coincides with the center point of the fan-out semiconductor package, the one or more semiconductor dies are in the cavity to be adjacent to one side of the cavity, and the one or more dummy dies are in a remaining space within the cavity, the remaining space being an area of the cavity that is not occupied by the one or more semiconductor dies.

5. The fan-out semiconductor package of claim 2, wherein a planar area occupied by the one or more semiconductor dies and the one or more dummy dies is 90% or more of a total planar area of the cavity.

6. The fan-out semiconductor package of claim 5, wherein the total planar area of the cavity is 80% or more of an area according to an outermost contour of the substrate.

7. The fan-out semiconductor package of claim 1, wherein the substrate includes a plurality of cavities, and the one or more semiconductor dies and the one or more dummy dies are in different cavities.

8. The fan-out semiconductor package of claim 7, wherein planar regions of the plurality of cavities are symmetrical with respect to a planar center point of the substrate.

9. The fan-out semiconductor package of claim 8, wherein
the substrate has a quadrangle shape,
the plurality of cavities include one cavity at the planar center point of the substrate and configured to accommodate the semiconductor die, and the plurality of cavities further include four cavities at four side portions of the substrate and configured to accommodate the one or more dummy dies, respectively, and
the four cavities have a same size and are symmetrical with respect to the planar center point of the substrate.

10. The fan-out semiconductor package of claim 8, wherein
the substrate has a quadrangle shape,
the plurality of cavities include one cavity at the planar center point of the substrate and configured to accommodate the semiconductor die, and the plurality of cavities further include four cavities for the dummy die at four corners of the substrate, respectively, and
the four cavities have a same size and are symmetrical with respect to the planar center point of the substrate.

11. The fan-out semiconductor package of claim 1, wherein the substrate includes a plurality of cavities, and a total planar area of the plurality of cavities is 80% or more of an area according to an outermost contour of the substrate.

12. The fan-out semiconductor package of claim 1, wherein the substrate further includes a plurality of conductive vias, and the lower redistribution layer is further electrically connected to the plurality of conductive vias.

13. The fan-out semiconductor package of claim 1, further comprising:
an additional semiconductor die stacked on a top surface of the upper redistribution layer through a solder bump.

14. The fan-out semiconductor package of claim 13, wherein the one or more semiconductor dies includes a non-memory semiconductor and the additional semiconductor die includes a memory semiconductor.

15. The fan-out semiconductor package of claim 1, wherein the one or more dummy dies include a dummy die that does not include a through silicon via (TSV).

16. A fan-out semiconductor package, comprising:
a lower redistribution layer;
a plurality of solder bumps on a bottom surface of the lower redistribution layer;
one or more semiconductor dies on a top surface of the lower redistribution layer;
one or more dummy dies on the top surface of the lower redistribution layer at a region where the one or more semiconductor dies are not disposed, the one or more dummy dies each including a plurality of through silicon vias;
an upper redistribution layer across first top surfaces of the one or more semiconductor dies and second top surfaces of the one or more dummy dies; and
a mold material filling an empty space between the lower redistribution layer and the upper redistribution layer,
wherein the upper redistribution layer and the lower redistribution layer are electrically connected only through at least some of the plurality of through silicon vias.

17. The fan-out semiconductor package of claim 16, wherein the one or more dummy dies include a plurality of dummy dies, and the plurality of dummy dies have a same size and have a same number and a same dispositions of through silicon vias.

18. The fan-out semiconductor package of claim 16, wherein a planar area occupied by the one or more semiconductor dies and the one or more dummy dies is 80% or more of a total planar area of the lower redistribution layer.

19. A method for manufacturing a fan-out semiconductor package, comprising:
fixing a substrate on a carrier, the substrate having a quadrangle frame shape and including a cavity;
attaching a semiconductor die at a center of the cavity so that a bottom surface of the semiconductor die, at which a plurality of connection terminals are provided, is in contact with the carrier;
attaching a plurality of dummy dies to a remaining region within the cavity where the semiconductor die is not disposed, each of the plurality of dummy dies including a plurality of through silicon vias;
filling an empty space within the cavity with a filler by supplying the filler from an upper portion of the cavity;
grinding top surfaces of the substrate, the semiconductor die, and the plurality of dummy dies to expose the plurality of through silicon vias of the plurality of dummy dies;
providing an upper redistribution layer on the top surfaces of the substrate, the semiconductor die, and the plurality of dummy dies such that the upper redistribution layer is electrically connected to at least some of the plurality of through silicon vias of the plurality of dummy dies;
providing a lower redistribution layer on bottom surfaces of the substrate, the semiconductor die, and the plurality of dummy dies such that the lower redistribution layer is electrically connected to at least some of the plurality of connection terminals of the semiconductor die and the plurality of through silicon vias of the plurality of dummy dies; and
providing a plurality of solder bumps on a bottom surface of the lower redistribution layer.

20. The method of claim 19, further comprising:
stacking an additional semiconductor die on a top surface of the upper redistribution layer with a plurality of solder bumps interposed therebetween.
